(19) United States
(12) Patent Application Publication
(10) Pub. No.: US 2010/0073084 A1
(43) Pub. Date: Mar. 25, 2010

(54) SYSTEMS AND METHODS FOR A LEVEL-SHIFTING HIGH-EFFICIENCY LINC AMPLIFIER USING DYNAMIC POWER SUPPLY

(75) Inventors: Joonhoi Hur, Atlanta, GA (US); Kwan-Woo Kim, Sunnyvale, CA (US); Kyutae Lim, Alpharetta, GA (US); Chang-Ho Lee, Marietta, GA (US); Haksun Kim, Daejeon (KR); Joy Laskar, Marietta, GA (US)

Correspondence Address: SUTHERLAND ASBILL & BRENNAN LLP, 999 PEACHTREE STREET, N.E., ATLANTA, GA, 30309, US

(73) Assignee: SAMSUNG ELECTRO-MECHANICS COMPANY, LTD., Gyunggi-Do (KR)

(21) Appl. No.: 12/563,710

(22) Filed: Sep. 21, 2009

Related U.S. Application Data
(60) Provisional application No. 61/098,529, filed on Sep. 19, 2008.

(51) Int. Cl. H03F 3/68

(52) U.S. Cl. 330/124 R

(57) ABSTRACT

Systems and methods may be provided for a LINC system having a level-shifting LINC amplifier. The systems and methods may include a dynamic power supply that is adjustable to provide at least a first voltage supply level and a second voltage supply level higher than the first voltage supply level; a first power amplifier that amplifies a first component signal to generate a first amplified signal; a second power amplifier that amplifiers a second component signal to generate a second amplified signal, where the first component signal and the second component signal are components of an original signal, where the first component signal and the second component signal each have a constant envelope, and where the original signal has a non-constant envelope, and where the first and second power amplifiers are biased at the first voltage supply level or the second voltage supply level based upon an analysis of an amplitude of the original signal.

### RELATED APPLICATION

The present application claims priority to U.S. Provisional Application No. 61/098,529, filed on Sep. 19, 2008, and entitled “APPARATUSES AND METHODS FOR A LEVEL-SHIFTING HIGH-EFFICIENCY LINC AMPLIFIER USING CLASS-E AMPLIFIER AND DYNAMIC POWER SUPPLY.” The foregoing application is hereby incorporated by reference in its entirety.

### FIELD OF THE INVENTION

The present invention relates generally to a linear amplifier with nonlinear components (LINC) amplifier having a high efficiency through the use of a dynamic power supply.

### BACKGROUND OF THE INVENTION

Linear amplifier with nonlinear components (LINC) is a power linearization method which offers both high linearity and high power amplifier (PA) efficiency for wireless transmitters. A conventional LINC system makes a linear system by combining two constant envelope nonlinear signals that have different phase information. In particular, a signal may be divided into two different phase signals having the same amplitude. The two different phase signals may be combined to restore the original signal.

In the conventional LINC system, a high-efficiency switching PA can be used because linearity is not needed. A high-efficiency switching PA is more efficient than a linear PA. Accordingly, from the standpoint of the PA, a high-efficiency switching PA tends to increase the efficiency of the LINC system.

However, in terms of system efficiency, the conventional LINC system is not optimized with use of constant envelope vector signals. In particular, the conventional LINC system utilizes two constant envelope vector signals to represent a linear vector signal regardless of the original OFDM (orthogonal frequency-division multiplexing) signal's amplitude. The signal component separator (SCS) does this function and uses the following equations:

$$es = j \times \sqrt{\frac{{\vert O F D M \vert}_{max}^{2}}{{\vert O F D M \vert}_{ins}^{2} - 1}}$$

$$S 1 = 0.5 * {\vert O F D M \vert}_{ins} * ( 1 + es ) / ( 0.5 * {\vert O F D M \vert}_{max} )$$

$$S 2 = 0.5 * {\vert O F D M \vert}_{ins} * ( 1 - es ) / ( 0.5 * {\vert O F D M \vert}_{max} )$$

As a result of above equation, two same amplitude signals S1 & S2 are generated. The original OFDM signal is restored from the two same amplitude signals S1 & S2.

However, in this scheme, the same power is used regardless of the original signal's power. For example, it needs the same power to restore a zero power output as to restore a maximum power out. To use large power to restore a zero power output signals makes for poor system efficiency.

Accordingly, there is a need in the industry for a level-shifting LINC amplifier in which a large-amplitude vector signals are utilized for restoring a large-amplitude signal while small-amplitude vector signals are utilized for restoring a small-amplitude signal.

### SUMMARY OF THE INVENTION

Embodiments of the present invention may provide a level shifting dynamic power supply LINC amplifier. The LINC amplifier may provide for high efficiency linear amplification using a signal component separator, a dynamic power supply, switching power amplifiers (e.g., class E non-linear amplifiers), and a power combiner. Pre-distortion may be utilized with the LINC amplifier to retain a linear system. The system can be implemented with one chip and an output combiner.

According to an example embodiment of the invention, there is a LINC system. The LINC system may include a dynamic power supply that is adjustable to provide at least a first voltage supply level and a second voltage supply level higher than the first voltage supply level; a first power amplifier that amplifies a first component signal to generate a first amplified signal; a second power amplifier that amplifiers a second component signal to generate a second amplified signal, where the first component signal and the second component signal are components of an original signal, where the first component signal and the second component signal each have a constant envelope, and where the original signal has a non-constant envelope, and where the first and second power amplifiers are biased at the first voltage supply level or the second voltage supply level based upon an analysis of an amplitude of the original signal.

According to another example embodiment of the invention, there is a method. The method may include providing a dynamic power supply that is adjustable to provide at least a first voltage supply level and a second voltage supply level higher than the first voltage supply level; amplifying a first component signal by a first power amplifier to generate a first amplified signal; amplifying a second component signal by a second power amplifier to generate a second amplified signal, where the first component signal and the second component signal are components of an original signal, where the first component signal and the second component signal each have a constant envelope, and where the original signal has a non-constant envelope; and biasing the first and second power amplifiers at the first voltage supply level or the second voltage supply level based upon an analysis of an amplitude of the original signal.

### BRIEF DESCRIPTION OF THE DRAWINGS

Having thus described the invention in general terms, reference will now be made to the accompanying drawings, which are not necessarily drawn to scale, and wherein:

FIG. 1 illustrates an example multi-level LINC (MLINC) system in accordance with an example embodiment of the invention.

FIG. 2 illustrates an example circuit representation of an example power combiner, according to an example embodiment of the invention.

FIG. 3 provides example diagrams that compare a conventional LINC amplifier approach with an example multi-level LINC amplifier approach, according to an example embodiment of the invention.

FIG. 4 illustrates an example flow diagram for level shifting that may be utilized by an example signal component separator (SCS), according to an example embodiment of the invention.

FIG. 5 illustrates an example system efficiency simulation, according to an example embodiment of the invention.

FIG. 6 illustrates an example uneven multi-level LINC (UMLINC) system, according to an example embodiment of the invention.

FIG. 7 illustrates an example flow diagram 700 for level shifting that may be utilized by an example uneven multi-level signal component separator (UMSCS), according to an example embodiment of the invention.

FIGS. 8A-8C illustrates example signals that may be generated by an example uneven multi-level signal component separator (UMSCS), according to an example embodiment of the invention.

FIG. 9 shows an example system efficiency comparison for a LINC system, an MLINC system, and an example UMLINC system, based upon a WiMAX signal, according to an example embodiment of the invention.

FIG. 10 illustrates example constellation and spectrum simulation results for a WiMAX system, according to an example embodiment of the invention.

### DETAILED DESCRIPTION OF THE INVENTION

Embodiments of the present invention now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

Embodiments of the invention may provide for a level-shifting LINC amplifier in which large-amplitude component signals are utilized for restoring a large-amplitude signal while small-amplitude component signals are utilized for restoring a small-amplitude signal, thereby improving system efficiency. The LINC amplifier may provide for high efficiency linear amplification using a signal component separator, a dynamic power supply, switching power amplifiers (e.g., class E non-linear amplifiers), and a power combiner. In addition, example embodiments of the invention may provide for pre-distortion for amplitude/phase error correction of the LINC amplifier.

### Example Embodiment of MLINC System

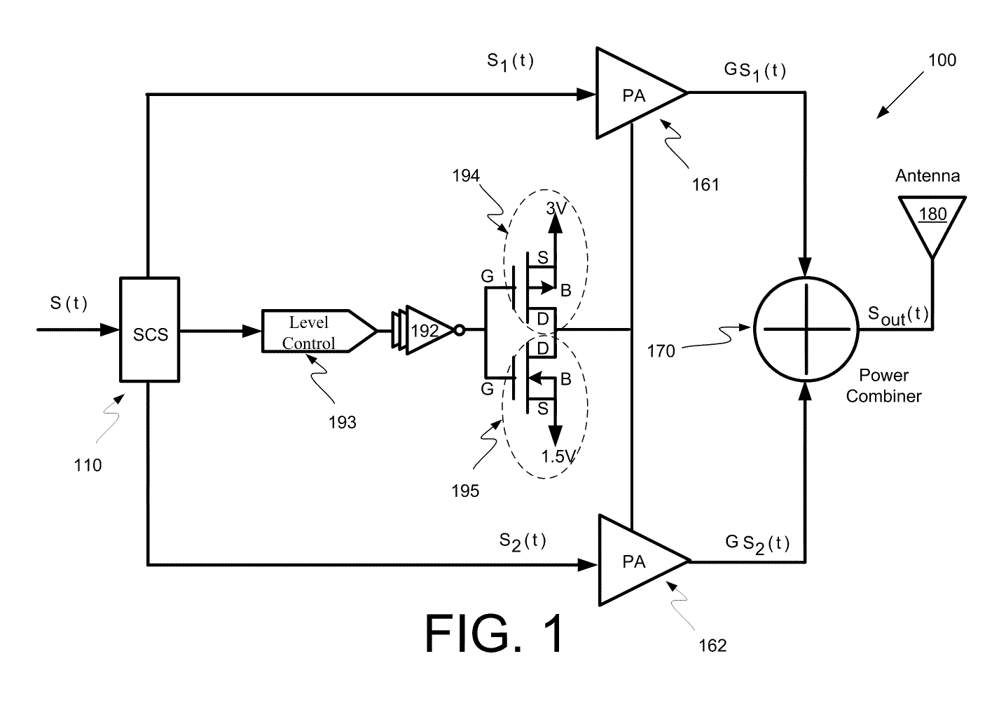

FIG. 1 illustrates a multi-level LINC (MLINC) system 100 in accordance with an example embodiment of the invention. The system 100 may include a signal component separator (SCS) 110; power amplifiers 161, 162; a power combiner 170. The LINC system 100 may also include a dynamic power supply that may be comprised of switches 194, 195.

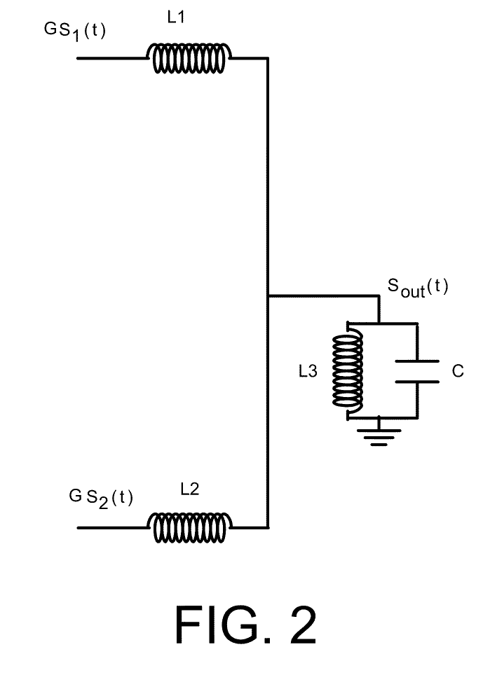

The signal component separator 110 may be operative to split an original signal S(t) (e.g., an original OFDM signal or another modulated signal) having a non-constant envelope (e.g., a time-varying envelope) into two component signals S₁(t), S₂(t) that each have a constant envelope. The power amplifiers 161, 162 may be operative to amplify the respective component signals S₁(t), S₂(t) to generate respective amplified component signals GS₁(t), GS₂(t). The two amplified components signals GS₁(t), GS₂(t) may be combined by a power combiner 170 to generate output signal Sₒᵤₜ(t), which may be a radio frequency (RF) output that is transmitted by an antenna 180. The power combiner 170 may be a non-isolated power combiner such as a chireix combiner, according to an example embodiment of the invention. A circuit representation of an example power combiner 170 is illustrated in FIG. 2, according to an example embodiment of the invention.

Still referring to FIG. 1, the power amplifiers 161, 162 may be operative as class-E power amplifiers in accordance with a class-E configuration, according to an example embodiment of the invention. The power amplifiers 161, 162 may be non-linear amplifiers, according to an example embodiment of the invention. The power amplifiers 161, 162 may be operative as level-shifting LINC amplifiers through the use of a dynamic power supply, according to an example embodiment of the invention.

The dynamic power supply may receive a level control 193 that is generated by the signal component separator 110 based upon the amplitude of the original signal S(t). The signal control 193 may direct the dynamic power supply to adjust the biasing level of the power amplifiers 161, 162 and/or power combiner 170. By adjusting the biasing level of power amplifiers 161, 162, the output amplitude levels of the amplified component signals GS₁(t), GS₂(t) may be adjusted up or down, according to an example embodiment of the invention.

As shown in FIG. 1, the example dynamic power supply may have access to at least two power (voltage) supply levels (e.g., 3V or 1.5V) via power switches 194, 195. The switches 194, 195 may be utilized in the dynamic power supply to select between at least two power supply levels. The selected power level may be used to bias the power amplifiers 161, 162 and/or power combiner 170. According to an example embodiment, when the level control 193 determines that the power amplifiers 161, 162 are to be biased at a higher power (voltage) supply level (e.g., 3V), the level control 193 directs (e.g., via voltage supply 192) the switch 194 to close in order to connect to the higher supply level (e.g., 3V) while the switch 195 may be opened to prevent a connection to the lower supply level (e.g., 1.5V). In contrast, when the level control 193 determines that the power amplifiers 161, 162 and/or power combiner 170 are to be biased at a lower power (voltage) supply level (e.g., 1.5V), the level control 193 directs the switch 195 to close in order to connect to the lower power supply level (e.g., 1.5V) while the switch 194 may be opened to prevent a connection to the higher supply level (e.g., 3V).

It will be appreciated that the switches 194, 195 may be implemented using one or more transistors, including MOSFETs. As shown in FIG. 1, the switch 194 may be a first MOSFET having a first gate, first source, first drain, and first body (bulk), and the switch 195 may be a second MOSFET also having a second gate, second source, second drain, and second body (bulk). According to an example configuration, the first bulk may be connected (e.g., electrically) to the first source, which may be connected to the higher supply level (e.g., 3V). Similarly, the second bulk may be connected to the second source, which may be connected to the lower supply level (e.g., 1.5V). The first gate may be connected to the second gate, and also to a voltage source 192. The first drain may be connected to the second drain, which are both connected to bias ports of the power amplifier 161, 162.

However, in an example embodiment of the invention, other components (e.g., a varistor) may also be used to switch between at least two power supply levels in discrete or non-discrete steps. It will also be appreciated that many variations of switching between at least two power supply levels are available without departing from example embodiments of the invention. According to one variation, both switches 194, 195 may be connected to the same power supply level. A higher supply power level may be achieved by simultaneously connecting to the two power supply levels (e.g., 1.5V+1.5V=3.0V) while a lower supply level may be achieved by connecting to only one of the two power supply levels (e.g., 1.5V+0V=1.5V).

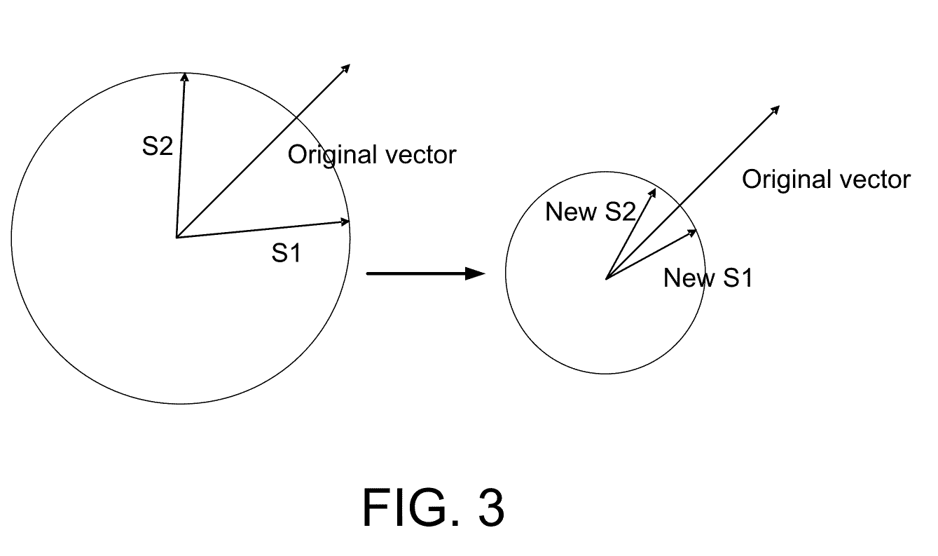

FIG. 3 provides example diagrams that compare a conventional LINC amplifier approach with an example multi-level LINC amplifier approach, according to an example embodiment of the invention. The conventional LINC amplifier approach is illustrated on the left diagram in which large-amplitude component signals (original S1 & original S2) are utilized to restore an original vector that is a small-amplitude signal. By contrast, the example multi-level LINC amplifier approach is able to restore the same original vector that is a small-amplitude signal by using smaller amplitude component signals (New S1 & New S2). For example, the original S1 and S2 may have a magnitude that is based upon a maximum magnitude value while the new S1 and S2 may have a magnitude that is based upon a lower magnitude value, as described herein. Thus, the example level-shifting LINC amplifier may more efficient than a conventional LINC amplifier. Indeed, as described herein, the level-shifting LINC amplifier in accordance with example embodiments of the invention may vary the amplitude of the component signals depending on a size of the original signal S(t).

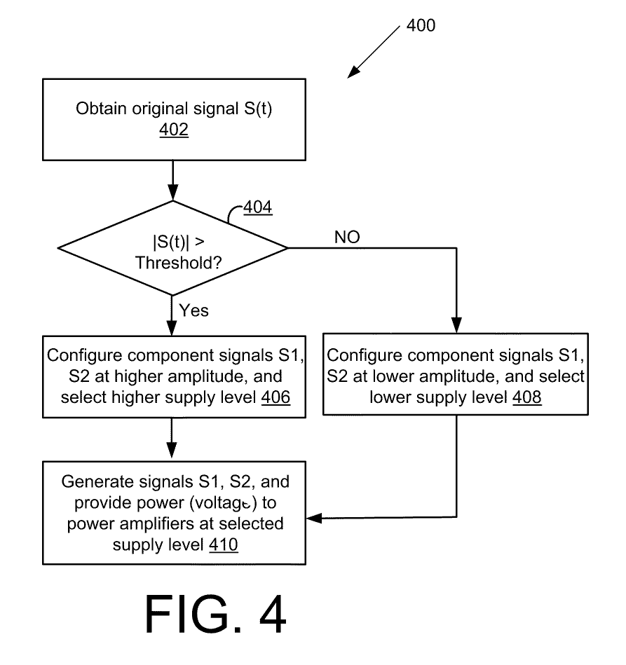

FIG. 4 illustrates an example flow diagram 400 for level shifting that may be utilized by an example signal component separator (SCS), according to an example embodiment of the invention. Indeed, an example SCS in accordance with an embodiment of the invention may be operative to provide two or more envelope levels.

Turning now to block 402, the original signal (e.g., S(t) such as an OFDM signal) or a representation of the original signal may be obtained by the SCS. In block 402, the magnitude of an instance of the original signal (e.g., |OFDM| instance) may be determined. Block 404 may determine whether the magnitude of an instance of the original signal (e.g., |OFDM| instance) is greater than a threshold magnitude value (e.g., |OFDM|ₜₕ). It will be appreciated that the threshold value may be selected based upon a power density function (PDF) of the original signal S(t). If the magnitude of an instance of the original signal is greater than the threshold magnitude value, then the SCS may be configured to generate the component signals S1, S2 at a higher or maximum amplitude value. Likewise, the SCS may provide a level control that selects a full or higher power (voltage) supply level (e.g., V_{supply}=V_{dd}), as illustrated in block 406. On the other hand, if the magnitude of an instance of the original signal is less than or equal to the threshold value, then the SCS may configure the component signals S1, S2 to be generated at a lower or threshold amplitude value. Likewise, the SCS may provide a level control that selects a lower power (voltage) supply level (e.g., V_{supply}=0.5*V_{dd}), as illustrated in block 408. In block 410, the component signals S1, S2 may be generated as configured, and the dynamic power supply may respond to the level control by directing the proper configuration of the power supply switches such that the LINC amplifiers are biased using either the designated higher or lower power supply level. Accordingly, if the LINC amplifier is biased with the lower power (voltage) supply level, then the component vector signals S1, S2 can be generated by the SCS with lower amplitudes, according to an example embodiment of the invention. On the other hand, if the LINC amplifier is biased with the higher power supply level, then the component vector signal S1, S2 can be generated by the SCS with higher amplitudes.

The lower and higher amplitudes for the component vector signals S1, S2 will now be discussed in conjunction with an example implementation to provide additional context. In the example implementation, if an |OFDM| instance (i.e., |OFDM|ᵢₙₛ) magnitude or other original signal instance magnitude is smaller than or equal to a threshold magnitude value (e.g., |OFDM|ₜₕ), then the component vector signals S1, S2 can be generated with a lower amplitude by using the threshold magnitude value |OFDM|ₜₕ or a lower magnitude value. In this scenario, the associated V_{supply} for biasing the LINC amplifier (e.g., amplifiers 161, 162) would be lowered, perhaps to 0.5*V_{dd}, using the power switch, as provided below:

$$\text{=} \text{>} When {\vert O F D M \vert}_{ins} \leq {\vert O F D M \vert}_{th}$$

$$es = j \times \sqrt{\frac{{\vert O F D M \vert}_{th}^{2}}{{\vert O F D M \vert}_{ins}^{2} - 1}}$$

$$S 1 = 0.5 * {\vert O F D M \vert}_{ins} * ( 1 + es ) / ( 0.5 * {\vert O F D M \vert}_{th} )$$

$$S 2 = 0.5 * {\vert O F D M \vert}_{ins} * ( 1 - es ) / ( 0.5 * {\vert O F D M \vert}_{th} )$$

$${V}_{supply} = 0.5 * {V}_{dd}$$

On the other hand, if an |OFDM| instance (i.e., |OFDM|ᵢₙₛ) magnitude or other original signal instance is larger than a threshold magnitude value (i.e., |OFDM|ₜₕ), then the component vector signals S1, S2 can be set to a higher amplitude by using a maximum magnitude value |OFDM|ₘₐₓ (e.g., available with maximum power supply level) or a higher magnitude value. In this scenario, the associated V_{supply} for biasing the LINC amplifier would be increased, perhaps to V_{dd}, using the power switch, as provided below:

$$\text{=} \text{>} When {\vert O F D M \vert}_{ins} > {\vert O F D M \vert}_{th}$$

$$es = j \times \sqrt{\frac{{\vert O F D M \vert}_{max}^{2}}{{\vert O F D M \vert}_{ins}^{2} - 1}}$$

$$S 1 = 0.5 * {\vert O F D M \vert}_{ins} * ( 1 + es ) / ( 0.5 * {\vert O F D M \vert}_{max} )$$

$$S 2 = 0.5 * {\vert O F D M \vert}_{ins} * ( 1 - es ) / ( 0.5 * {\vert O F D M \vert}_{max} )$$

$${V}_{supply} = {V}_{dd}$$

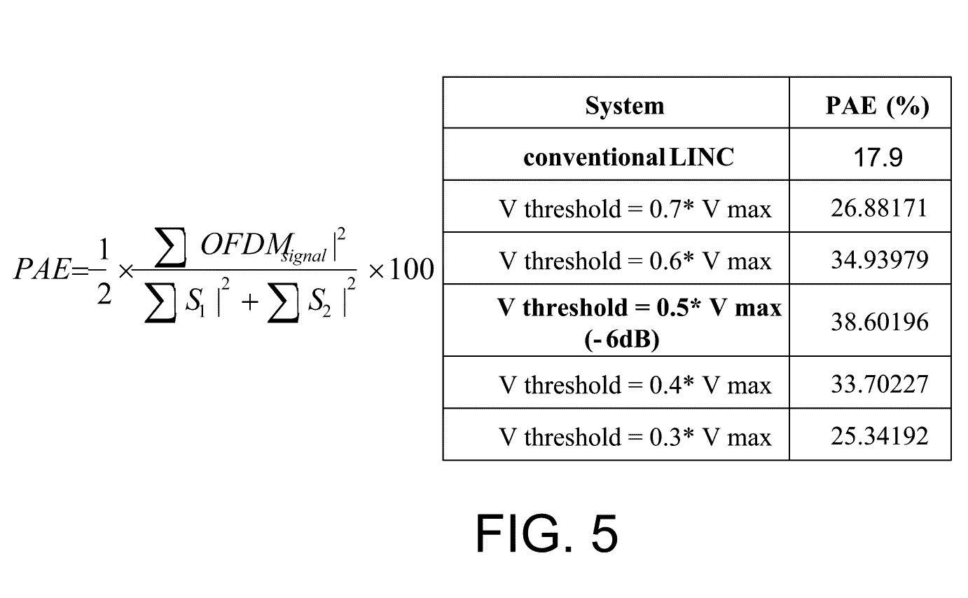

FIG. 5 illustrates an example system efficiency simulation, according to an example embodiment of the invention. An example system efficiency may be determined according to

$$PAE = \frac{1}{2} \times \frac{\sum {\vert O F D {M}_{signal} \vert}^{2}}{\sum {\vert {S}_{1} \vert}^{2} + \sum {\vert {S}_{2} \vert}^{2}} \times 100.$$

To decide on an |OFDM| threshold for highest system efficiency, the simulation can be done with changing the |OFDM| threshold (amplitude changing decision level). According to an example embodiment of the invention, the system simulation result of FIG. 5 indicates that the system efficiency is optimal when Vth=½*Vmax. Indeed, when |OFDM| threshold=½*|OFDM| max, the system efficiency is 38.6%. This is more than 20% better compared to a conventional LINC system. It will be appreciated that while specific examples of threshold voltages have been illustrated in FIG. 5, other threshold voltages may be utilized without departing from example embodiments of the invention.

### Example Embodiment of UMLINC System

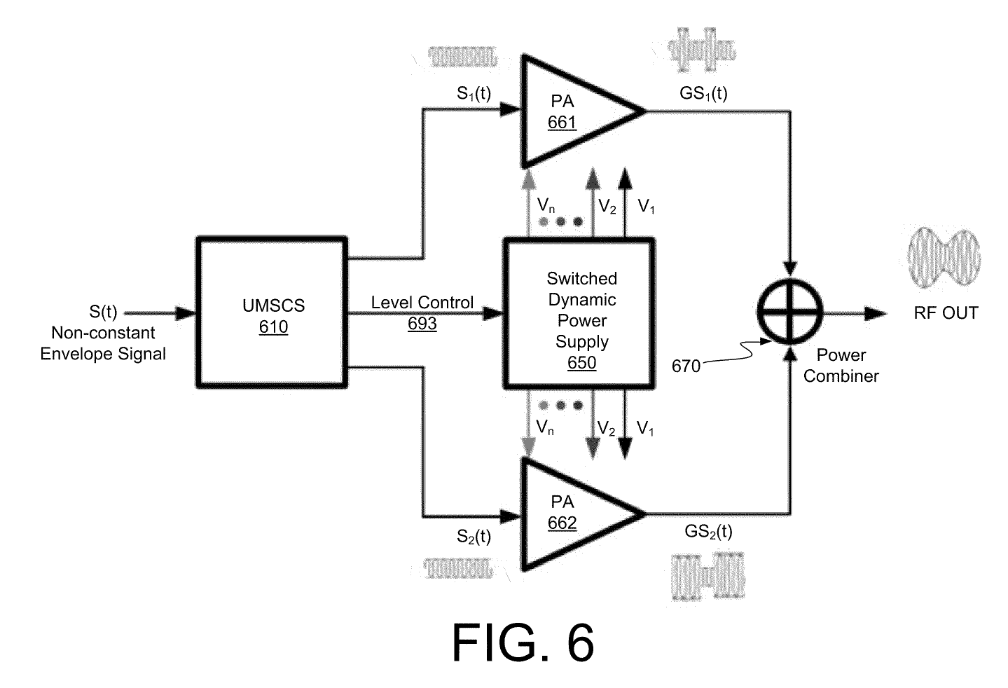

FIG. 6 illustrates an example uneven multi-level LINC (UMLINC) system 600, according to an example embodiment of the invention. The system 600 may include an uneven multi-level signal component separator (UMSCS) 610; a switched dynamic power supply 650; high efficiency switching power amplifiers (PAs) 661, 662; and a power combiner 670. It will be appreciated that the switched dynamic power supply 650 may be implemented using components similarly described with respect to FIG. 1 (e.g., switches 194, 195) without departing from example embodiments of the invention.

The UMSCS 610 may be operative to split an original signal S(t) (e.g., an original OFDM signal or another modulated signal) having a non-constant envelope into two component phase signals S₁(t), S₂(t) that each have a constant envelope. The two component phase signals S₁(t), S₂(t) may have different phases, according to an example embodiment of the invention. The phase signals S₁(t), S₂(t) may be provided to respective inputs of the power amplifiers 661, 662. In addition, the UMSCS 610 may generate a level control 693 that utilized by the switched dynamic power supply 650 to configure or change the supply voltage provided to the power amplifiers 661, 662. It will be appreciated that the power amplifiers 661, 662 may non-linear amplifiers provided in a class-E configuration, according to an example embodiment of the invention.

To prevent linearity problems, the power combiner 670 may be an isolated combiner, where the efficiency may be maximized when both inputs are in phase. It will be appreciated that the number of maximum efficiency points of a multi-level LINC transmitter that utilizes a typical signal component separator (SCS) may equal the number of levels of the power supply, n. However, the use of an example uneven multi-level UMSCS 610 in the LINC system 600 may increase the maximum number of efficiency points from n to n′, defined as:

$${n}^{′} = {}_{n}^{}{H}{}_{2}^{} = {}_{n + 1}^{}{C}{}_{2}^{} = \frac{( n + 1 ) !}{2 ! \cdot ( n - 1 ) !} .$$

This increase in the number of maximum efficiency points may improve the total system efficiency, according to an example embodiment of the invention.

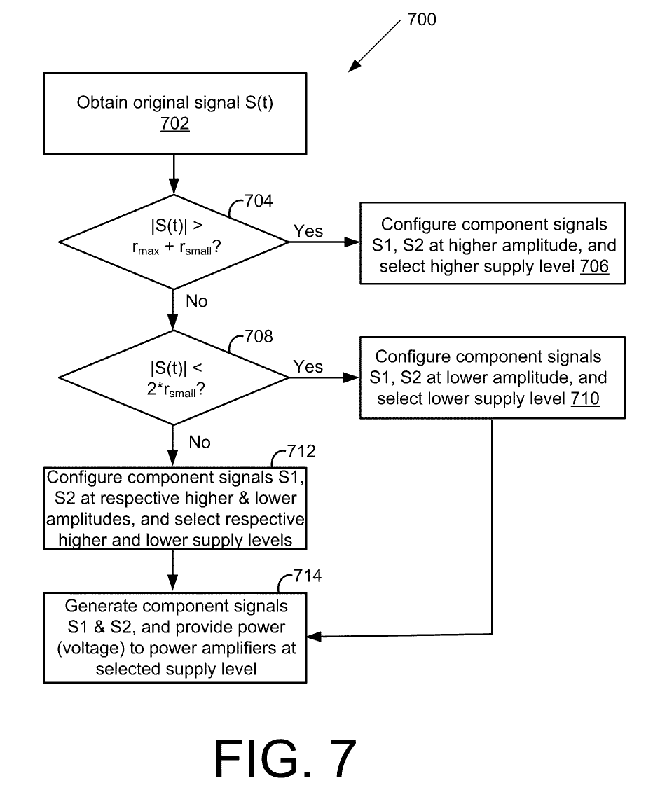

FIG. 7 illustrates an example flow diagram 700 for level shifting that may be utilized by an example uneven multi-level signal component separator (UMSCS) such as UMSCS 610, according to an example embodiment of the invention. It will be appreciated that the example outputs of the UMSCS may be based upon two power supplies that can be provided by the switched dynamic power supply. The outputs of the two power supplies may be proportional to a small amplitude value, rₛₘₐₗₗ, which may be chosen based on the signal power density function (PDF) of the original signal S(t), and maximum amplitude value, rₘₐₓ, which may be about half of the maximum signal envelope of the original signal S(t). In an example embodiment of the invention, the small amplitude value, rₛₘₐₗₗ, may be selected based upon efficiency determined during simulation. The value of rₛₘₐₗₗ may be different according to the PDF of the signal source. For example, an rₛₘₐₗₗ value for a WiMax signal may be set at 0.346×rₘₐₓ, according to an example embodiment of the invention. It will be appreciated, however, that the value of rₛₘₐₗₗ may be set to be another value or percentage (e.g., 25%-50%) of rₘₐₓ without departing from an example embodiment of the invention.

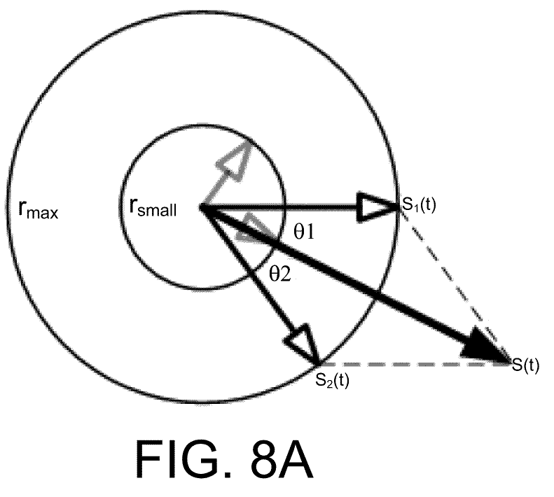

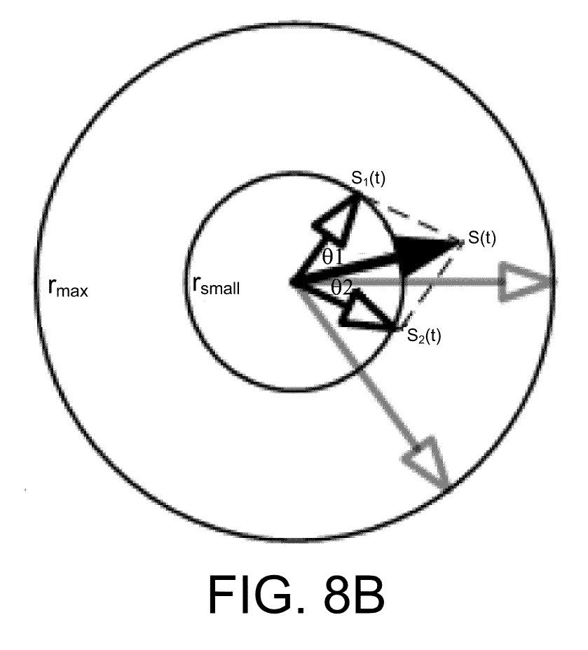

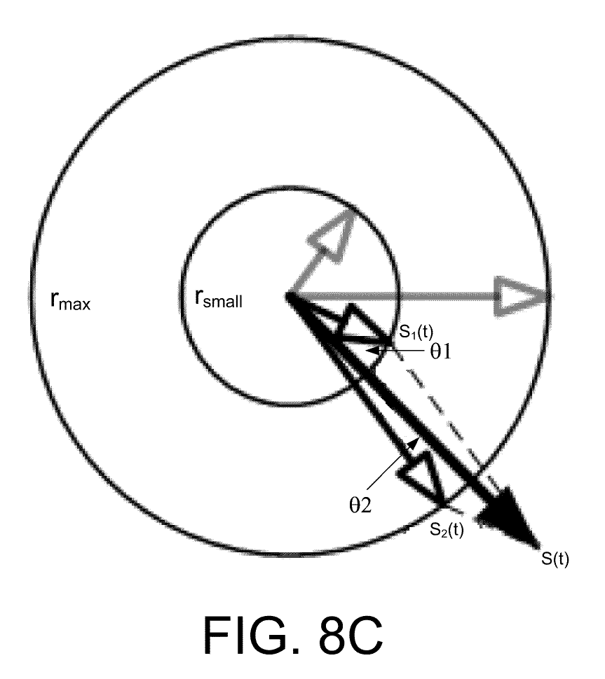

Turning now to block 702, the original signal S(t) may be obtained by the UMSCS. In block 702, the magnitude of an instance of the original signal S(t) may be determined. In block 704, if the magnitude of the instance of the original signal S(t) is greater than a sum of the small amplitude value rₛₘₐₗₗ and the maximum amplitude value rₘₐₓ, then processing may proceed to block 706. In block 706, the UMSCS may be configured to generate two component signals S₁(t), S₂(t) of the same maximum amplitude value, rₘₐₓ, but with different phase information θ1 and θ2, as shown in FIG. 8A. Likewise, the UMSCS may also provide a level control that directs the dynamic power supply to supply the higher power (voltage) supply level to the power amplifiers.

On the other hand, if the magnitude of the instance of the original signal S(t) is not greater than a sum of the small amplitude value rₛₘₐₗₗ and the maximum amplitude value rₘₐₓ, then processing my proceed to block 708. Block 708 may determine whether the magnitude of an instance of the original signal S(t) is less than twice the small amplitude value rₛₘₐₗₗ. If so, then processing may proceed to block 710, where the UMSCS may be configured to generate two component signals S₁(t), S₂(t) of the same small amplitude value, rₛₘₐₗₗ, but with different phase information θ1 and θ2, as shown in FIG. 8B. The UMSCS may also provide a level control that directs the dynamic power supply to supply the lower power (voltage) supply level to the power amplifiers.

On the other hand, if the magnitude of an instance of the original signal S(t) is not less twice the small amplitude value rₛₘₐₗₗ (block 708), then the magnitude of the an instance of the original signal S(t) may be larger than larger than 2×rₛₘₐₗₗ, but smaller than rₛₘₐₗₗ+rₘₐₓ. Stated differently, the magnitude of an instance of the original signal S(t) may be between the values of rₛₘₐₗₗ and rₘₐₓ. In this case processing may proceed to block 712. In block 712, the UMSCS may generate two different signals S₁(t), S₂(t) with different amplitudes of rₛₘₐₗₗ and rₘₐₓ, and different phase information θ1 and θ2, as shown in FIG. 8C. The UMSCS may also provide a level control that directs the dynamic power supply to supply the lower power (voltage) supply level to the power amplifier associated with S₁(t), and the higher power (voltage supply level to the power amplifier associated with S₂(t), according to an example embodiment of the invention.

An example operation of an uneven multi-level signal component separator (UMSCS) such as UMSCS 610 will now be described in further detail. A complex polar representation of S(t) is S(t)=|S(t)|∠φ(t). The UMSCS outputs S₁(t), S₂(t) may change according to the amplitude and phase of the input signal S(t). These signals S₁(t), S₂(t) may be expressed as S₁(t)=|S₁(t)|∠(φ(t)−θ₁(t)) and S₂(t)=|S₂(t)|∠(φ(t)−θ₂(t)), where |S₁(t)| and |S₂(t)| are at a first magnitude (rₘₐₓ) or a second magnitude (rₛₘₐₗₗ), S(t)=S₁(t)+S₂(t), and θ₁ and θ₂ can be derived from the law of cosines as:

$${θ}_{1} ( t ) = {cos}^{- 1} ( \frac{{\vert S ( t ) \vert}^{2} + {\vert {S}_{2} ( t ) \vert}^{2} - {\vert {S}_{1} ( t ) \vert}^{2}}{2 \vert S ( t ) \vert \times \vert {S}_{2} ( t ) \vert} )$$

$$and$$

$${θ}_{2} ( t ) = {cos}^{- 1} ( \frac{{\vert S ( t ) \vert}^{2} + {\vert {S}_{1} ( t ) \vert}^{2} - {\vert {S}_{2} ( t ) \vert}^{2}}{2 \vert S ( t ) \vert \times \vert {S}_{1} ( t ) \vert} ) .$$

An example simulation with a 7 MHz bandwidth 64 QAM WiMAX signal may be used to verify the efficiency improvement and the feasibility of the UMLINC transmitter system. The total system efficiency can be expressed as follows:

System Efficiency=∫₀^{|S(t)|}^{ₘₐₓ}η_{PA}×η_{Comb}(|S(t)|)×P(|S(t)|)d|S(t)|, where η_{PA} is the PA efficiency, η_{Comb} is the power combiner efficiency, and P(|S(t)|) is the PDF according to the envelope of the signal S(t). For purpose of the simulation, the switching PAs and the isolated power combiner may be treated as ideal.

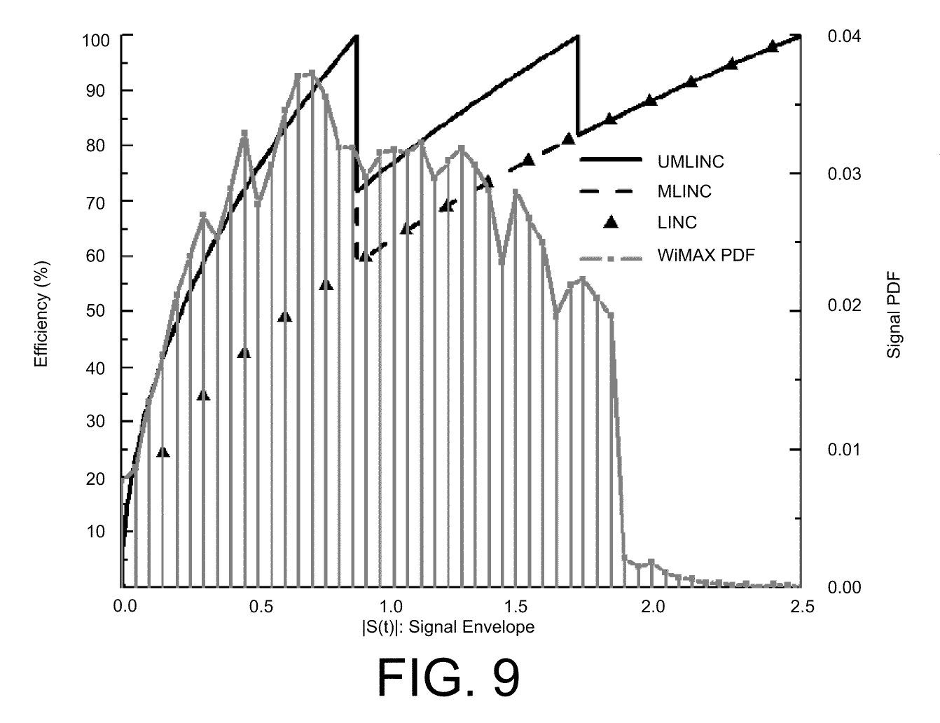

FIG. 9 shows an example system efficiency comparison for a LINC system, an MLINC system, and an example UMLINC system, based upon a WiMAX signal, according to an example embodiment of the invention. As shown in FIG. 9, for a conventional LINC system, the efficiency may be maximized when the signal envelope, |S(t)|, is maximized and decreases as |S(t)| decreases. However, as shown in FIG. 9, most of the WiMAX signal is in the small envelope range. Therefore, a conventional LINC system yields poor system efficiency. In an MLINC system that employs two power supplies, the efficiency in the low power range increases by using two small envelope signals having a small magnitude (rₛₘₐₗₗ) when the |S(t)| is small. However, the efficiency at the middle power levels may be low because only two maximum efficiency points exists. However, using uneven signal envelopes for the middle power range in the UMLINC system improves the efficiency at the middle power levels, as shown in FIGS. 8A-8C. The simulation results for the system efficiency of each system are shown in Table 1.

TABLE I
System Efficiency

| | | MLINC | UMLINC |
|---|---|---|---|
| | LINC | (power supply = 2) | (power supply = 2) |
| System Efficiency | 18% | 38.6% | 49.72% |
| Optimum Level | rₘₐₓ | rₛₘₐₗₗ = 0.51 × rₘₐₓ | rₛₘₐₗₗ = 0.346 × rₘₐₓ |

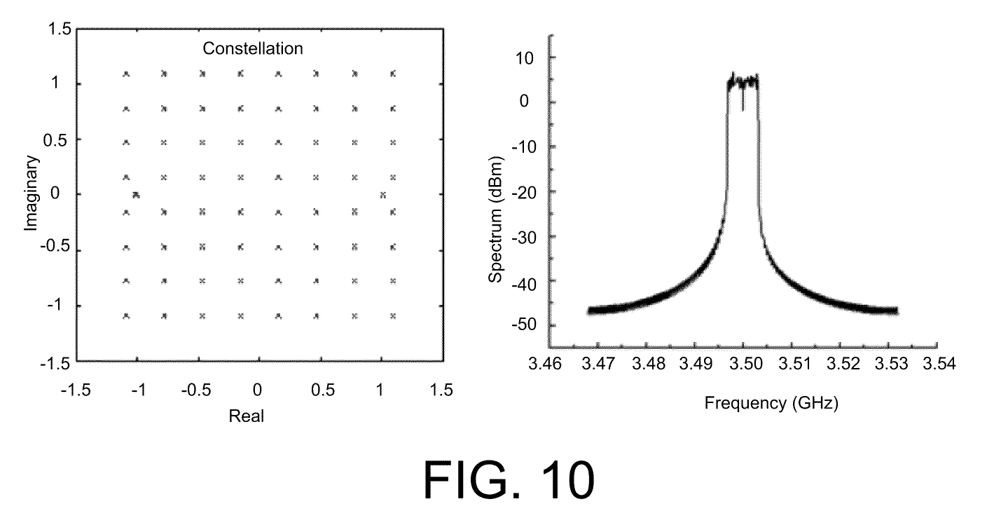

The constellation and spectrum simulation results for a WiMAX system are presented in FIG. 10, which exhibits no linearity degradation, according to an example embodiment of the invention.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A LINC system, comprising:
a dynamic power supply that is adjustable to provide at least a first voltage supply level and a second voltage supply level higher than the first voltage supply level;
a first power amplifier that amplifies a first component signal to generate a first amplified signal;
a second power amplifier that amplifiers a second component signal to generate a second amplified signal,
wherein the first component signal and the second component signal are components of an original signal, wherein the first component signal and the second component signal each have a constant envelope, and wherein the original signal has a non-constant envelope,
wherein the first and second power amplifiers are biased at the first voltage supply level or the second voltage supply level based upon an analysis of an amplitude of the original signal, wherein the first voltage supply level is higher than the second voltage supply level.

2. The LINC system of claim 1, wherein:
if the amplitude of the original signal is greater than a threshold value, then the first component signal and the second component signal are generated with respective amplitudes that are based upon a first value; and
if the amplitude of the original signal not greater than the threshold value, then the first component signal and the second component signal are generated with respective amplitudes that are based upon a second value less than the first value.

3. The LINC system of claim 2, wherein:
if the amplitudes of the first component signal and the second component signal are based upon a first value, then the first and second power amplifiers are biased at the first voltage supply level that is higher than the second voltage supply level; and
if the amplitudes of the first component signal and the second component signal are based upon a second value less than the first value, then the first and second power amplifiers are biased at the second voltage level that is less than the first voltage supply level.

4. The LINC system of claim 1, wherein:
if the magnitude of the original signal is greater than a first threshold value, then the first component signal and the second component signal are generated with respective amplitudes based upon a first value;
if the magnitude of the original signal less than a second threshold value, then the first component signal and the second component signal are generated with respective amplitudes based upon a second value less than the first value; and
if the amplitude of the original signal is less than the first threshold value but greater than the second threshold value, then the first component signal is generated with a first amplitude based upon the first value and the second component signal is generated with a second amplitude based upon the second value.

5. The LINC system of claim 4, wherein:
if the amplitudes of the first component signal and the second component signal are based upon a first value, then the first and second power amplifiers are biased at the first voltage supply level that is higher than the second voltage supply level;
if the amplitudes of the first component signal and the second component signal are based upon a second value less than the first value, then the first and second power amplifiers are biased at the second voltage level that is less than the first voltage supply level; and
if the amplitudes of the first component signal and the second component signal are based upon respective ones of the first value and the second value, then the first power amplifier is biased at the first voltage supply level and the second power amplifier is biased at the second voltage supply level.

6. The LINC system of claim 4, wherein the first threshold value equals a first sum of the first value and the second value, wherein the second threshold value equals twice the second value, wherein the first value is set to substantially one half of a maximum magnitude of the original signal.

7. The LINC system of claim 1, further comprising a signal component separator that splits the original signal having the non-constant envelope into the first component signal and the second component signal that each have the constant envelope.

8. The LINC system of claim 1, further comprising:
a power combiner that combines the first amplified signal and the second amplified signal to generate an output signal.

9. The LINC system of claim 1, wherein the dynamic power supply includes at least one switch for selecting between the first voltage supply level and the second voltage supply level.

10. The LINC system of claim 9, wherein the at least one switch includes a first transistor having a first gate, first source, and first drain, and a second transistor having a second gate, second source, and second drain, wherein the first source is connected to a first voltage supply for the first voltage supply level, wherein the second source is connected to a second voltage supply for the second voltage supply level, wherein the first gate is connected to the second gate, and wherein the first drain is connected to the second drain, wherein the first drain and the second drain are connected to bias ports of the first power amplifier and the second power amplifier.

11. A method for a LINC system, comprising:
providing a dynamic power supply that is adjustable to provide at least a first voltage supply level and a second voltage supply level higher than the first voltage supply level;
amplifying a first component signal by a first power amplifier to generate a first amplified signal;
amplifying a second component signal by a second power amplifier to generate a second amplified signal, wherein the first component signal and the second component signal are components of an original signal, wherein the first component signal and the second component signal each have a constant envelope, and wherein the original signal has a non-constant envelope; and
biasing the first and second power amplifiers at the first voltage supply level or the second voltage supply level based upon an analysis of an amplitude of the original signal, wherein the first voltage supply level is higher than the second voltage supply level.

12. The method of claim 11, wherein:
if the amplitude of the original signal is greater than a threshold value, then generating the first component signal and the second component signal with respective amplitudes that are based upon a first value; and
if the amplitude of the original signal not greater than the threshold value, then generating the first component signal and the second component signal with respective amplitudes that are based upon a second value less than the first value.

13. The method of claim 12, wherein:
if the amplitudes of the first component signal and the second component signal are based upon a first value, then the first and second power amplifiers are biased at the first voltage supply level that is higher than the second voltage supply level; and
if the amplitudes of the first component signal and the second component signal are based upon a second value less than the first value, then the first and second power amplifiers are biased at the second voltage level that is less than the first voltage supply level.

14. The method of claim 11, wherein:
if the magnitude of the original signal is greater than a first threshold value, then generating the first component signal and the second component signal with respective amplitudes based upon a first value;
if the magnitude of the original signal less than a second threshold value, then generating the first component signal and the second component signal with respective amplitudes based upon a second value less than the first value; and
if the amplitude of the original signal is less than the first threshold value but greater than the second threshold value, then generating the first component signal with a first amplitude based upon the first value and generating the second component signal with a second amplitude based upon the second value.

15. The method of claim 14, wherein:
if the amplitudes of the first component signal and the second component signal are based upon a first value, then the first and second power amplifiers are biased at the first voltage supply level that is higher than the second voltage supply level;
if the amplitudes of the first component signal and the second component signal are based upon a second value less than the first value, then the first and second power amplifiers are biased at the second voltage level that is less than the first voltage supply level; and
if the amplitudes of the first component signal and the second component signal are based upon respective ones of the first value and the second value, then the first power amplifier is biased at the first voltage supply level and the second power amplifier is biased at the second voltage supply level.

16. The method of claim 14, wherein the first threshold value equals a first sum of the first value and the second value, wherein the second threshold value equals twice the second value, wherein the first value is set to substantially one half of a maximum magnitude of the original signal.

17. The method of claim 11, further comprising:
splitting, via signal component separator, the original signal having the non-constant envelope into the first component signal and the second component signal that each have the constant envelope.

18. The method of claim 11, further comprising:
combining, by a power combiner, the first amplified signal and the second amplified signal to generate an output signal.

19. The method of claim 11, wherein the dynamic power supply includes at least one switch for selecting between the first voltage supply level and the second voltage supply level.

20. The method of claim 19, wherein the at least one switch includes a first transistor having a first gate, first source, and first drain, and a second transistor having a second gate, second source, and second drain, wherein the first source is connected to a first voltage supply for the first voltage supply level, wherein the second source is connected to a second voltage supply for the second voltage supply level, wherein the first gate is connected to the second gate, and wherein the first drain is connected to the second drain, wherein the first drain and the second drain are connected to bias ports of the first power amplifier and the second power amplifier.
